(19) United States
(12) Patent Application Publication
(10) Pub. No.: US 2007/0224342 A1
(43) Pub. Date: Sep. 27, 2007

(54) APPARATUS AND METHOD FOR FORMING ANTIREFLECTION FILM

(75) Inventor: GA-LANE CHEN, Santa Clara, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/556,137

(22) Filed: Nov. 2, 2006

(30) Foreign Application Priority Data
Mar. 21, 2006 (CN) 200610034599.6

(51) Int. Cl. B05D 5/06; C23C 16/00; B05D 3/12

(52) U.S. Cl. 427/162; 427/248.1; 427/346; 118/723 EB; 118/726

(57) ABSTRACT

An apparatus for forming an antireflection film includes a chamber, a rocking device, a substrate holder, at least one evaporation source, and at least one electron beam source. The substrate holder is disposed in the chamber and configured for holding the optical substrate thereon. The evaporation source is arranged in the chamber and opposite to the substrate holder. The at least one electron beam source is configured for producing electrons for bombarding the at least one evaporation source thereby dislodging material therefrom, the dislodged material is then deposited onto the optical substrate at an incident angle relative to a main plane of the optical substrate. The rocking device is configured for tilting the optical substrate onto the substrate holder so as to adjust the incident angle of the dislodged material.

### BACKGROUND OF THE INVENTION

1. Field of the Invention

The present invention relates to an apparatus and a method for forming an antireflection film on an optical substrate.

2. Description of Related Art

An antireflection film is generally used to prevent surface reflection on a lens. When surface reflection occurs, the light transmittance into the lens will be undesirably decreased. Antireflection films have been conventionally formed as a single-layered film or a multi-layered film by means of a vacuum evaporation method. A known apparatus for the evaporation and deposition of the antireflection film onto a lens to be coated generally includes a carrier configured (i.e., structured and arranged) for accommodating the lens, and an evaporation source vertically spaced from the carrier and configured for emitting a vapor stream onto the lens. The evaporation source is always fixedly positioned to face the lens, therefore thickness uniformity and optical transmittance of the antireflection film are low.

What is needed, therefore, is an apparatus for forming an antireflection film and a method for applying antireflection film.

### SUMMARY OF THE INVENTION

An apparatus for forming an antireflection film includes a chamber, a rocking device, a substrate holder, at least one evaporation source, and at least one electron beam source. The substrate holder is disposed in the chamber and configured for holding the optical substrate thereon. The evaporation source is arranged in the chamber opposite to the substrate holder. The at least one electron beam source is configured for producing electrons for bombarding the at least one evaporation source thereby dislodging material therefrom, the dislodged material is then deposited onto the optical substrate at an incident angle relative to a main plane of the optical substrate. The rocking device is configured for tilting the optical substrate onto the substrate holder so as to adjust the incident angle of the dislodged material.

Other advantages and novel features will become more apparent from the following detailed description when taken in conjunction with the accompanying drawings.

### BRIEF DESCRIPTION OF THE DRAWING

The components in the drawing are not necessarily drawn to scale, the emphasis instead being placed upon clearly illustrating the principles of the present apparatus and method. Moreover, in the drawing, like reference numerals designate corresponding parts.

FIG. 1 is a schematic plan view of an apparatus for applying antireflection film onto optical substrates according to a preferred embodiment.

### DETAILED DESCRIPTION OF THE EMBODIMENTS

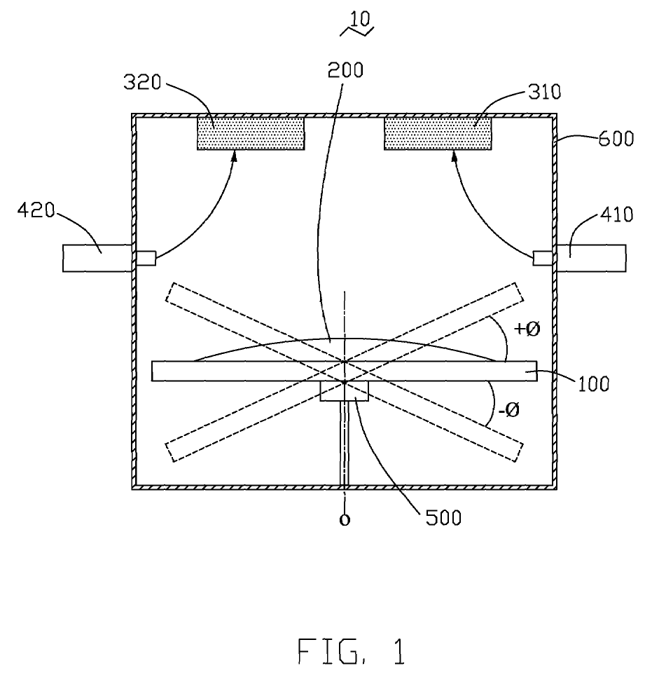

Referring to FIG. 1, an apparatus 10 for forming an antireflection film onto an optical substrate in accordance with a preferred embodiment is shown. The apparatus 10 generally includes a chamber 600, a substrate holder 100, a first evaporation source 310, a second evaporation source 320, a first electron-beam source 410, a second electron-beam source 420 and a rocking device 500. The chamber 600 can be evacuated via a vacuum pump (not shown). The substrate holder 100 is disposed in the chamber 600 and configured for holding an optical substrate 200 thereon. The first evaporation source 310 and the second evaporation source 320 are arranged in the chamber 600 and opposite to the substrate holder 100. The first electron-beam source 410 and the second electron-beam source 420 are configured for producing electrons for bombarding the first evaporation source 310 and the second evaporation source 320 respectively thereby dislodging material therefrom, thus depositing the dislodged material onto the optical substrate 200 at an incident angle relative to a main plane of the optical substrate 200. The rocking device 500 is mounted in the chamber 200 and configured for tilting the optical substrate 200 on the substrate holder 100 so as to adjust the incident angle of the dislodged material. Preferably, the rocking device 500 can allow the substrate holder 100 to rock to a predetermined angle ø. The substrate holder 100 has a pivot point (not shown), the substrate holder 100 can be tiltable about the pivot point. Therefore, the incident angle of the dislodged material can be adjusted periodically by the rocking device 500, a converted quantity of the incident angle of the dislodged material is equal to quantity of the predetermined angle ø. Thus, the antireflection film formed on the optical substrate 200 has better thickness uniformity and optical transmittance.

The optical substrate 200 may be a spherical lens or an aspheric lens. Material of the antireflection film is in the first evaporation source 310 and the second evaporation source 320. The material of the antireflection film can be applied onto the optical substrate 200 using thermal physical vapor deposition or electron beam physical vapor deposition. In the embodiment, the antireflection films can be formed using electron beam physical vapor deposition. The electron-beam sources 410, 420 are operated to melt and evaporate the materials of the antireflection films so that the materials form a vapor stream.

In the other embodiment of the present invention, the apparatus 10 may include one or more evaporation source. The apparatus 10 includes a plurality of evaporation sources when forming a plurality of layers of the antireflection film on the optical substrate 200. The different coating materials of the antireflection film are supplied by the evaporation sources. Preferably, quantity of layers of the antireflection film is equal to quantity of the evaporation sources.

Generally, the electron-beam sources 410, 420 and the evaporation sources 310, 320 are not arranged in a line, and it is necessary to accelerate and deflect the electrons to the first evaporation source 310 and the second evaporation source 320 respectively. In this embodiment, the apparatus 10 further includes a magnetic field generator configured for creating a magnetic field for accelerating the electrons. The chamber 600 is disposed in the magnetic field; the electrons can be accelerated and deflected to the evaporation sources.

A method for using the apparatus 10 as described above to form an antireflection film on an optical substrate such as a lens in accordance with a preferred embodiment is shown. The method includes the following steps.

Step 1: providing an apparatus 10 as described above.

Step 2: placing an optical substrate 200 to be coated on the substrate holder 100 that is placed in the chamber 600, and putting a first material of the antireflection film that is a high-refractive material in the first evaporation source 310 and a second material of the antireflection film that is a low-refractive material in the second evaporation source 320. The optical substrate 200 can be held attached to the substrate holder 100.

Step 3: melting and evaporating the first material of the antireflection film to form high-refractive material vapor stream by using the first electron-beam source 410, and tilting the substrate holder 100 to a predetermined angle ø to adjust the incident angle of the high-refractive material vapor stream, so as to coat a first layer having better thickness uniformity onto the optical substrate 200. The first material of the antireflection film is selected from the group consisting of TiO₂ (Titanium Dioxide), Nb₂O₅ (Niobium Pentaoxide), and Ta₂O₅ (Tantalum Pentoxide). In this step the first material of the antireflection film is TiO₂ and its refractive index is 2.35, and the thickness of the high-refractive material of the first layer should be in an approximate range from 100 nm (nanometer) to 150 nm.

Step 4: melting and evaporating the second material of the antireflection film to form low-refractive material vapor stream by using the second electron-beam source 420, and tilting the substrate holder 100 to a predetermined angle ø to adjust the incident angle of the low-refractive material vapor stream, so as to coat a second layer having better thickness uniformity onto the first layer. The second material of the antireflection film is SiO₂ (Silicon Dioxide) and should have a refractive index of about 1.46. The thickness of the low-refractive material of the second layer should be in the approximate range from 250 nm to 350 nm.

Step 5: melting and evaporating TiO₂ to form TiO₂ vapor stream by using the first electron-beam sources 410, and tilting the substrate holder 100 to a predetermined angle ø to adjust the incident of the TiO₂ vapor stream, thus applying a third layer having better thickness uniformity on the second layer. The thickness of the TiO₂ film of the first layer should be in an approximate range from 800 nm to 1200 nm. The other high-refractive material such as Nb₂O₅ and Ta₂O₅ placed in the other evaporation sources can be melted and evaporated to deposit the third layer having better thickness uniformity on the second layer.

Step 6: melting and evaporating the second material of the antireflection film to form a low-refractive material vapor stream by using the second electron-beam source 420, and tilting the substrate holder 100 to a predetermined angle ø to adjust the incident angle of the low-refractive material vapor stream, so as to coat a fourth layer having better thickness uniformity on the third layer. The second material of the antireflection film is generally SiO₂ (Silicon Dioxide). And the thickness of the low-refractive material of the second layer should be in an approximate range from from 700 nm to 1400 nm.

As described above, an antireflection film having multi-layer structure formed on the optical substrate, the antireflection film achieves approximately 97.5% to 99.5% transmissivity in a wavelength range of about 400 nm to 700 nm.

It is understood that the various above-described embodiments and methods are intended to illustrate rather than limit the invention. Variations may be made to the embodiments and methods without departing from the spirit of the invention. Accordingly, it is appropriate that the appended claims be construed broadly and in a manner consistent with the scope of the invention.

What is claimed is:

1. An apparatus for forming an antireflection film on an optical substrate, comprising:
a chamber;
a substrate holder disposed in the chamber configured for holding the optical substrate thereon;
at least one evaporation source arranged in the chamber opposite to the substrate holder;
at least one electron beam source configured for producing electrons for bombarding the at least one evaporation source thereby dislodging material therefrom, the dislodged material is then deposited onto the optical substrate at an incident angle relative to a main plane of the optical substrate;
a rocking device configured for tilting the optical substrate onto the substrate holder so as to adjust the incident angle of the dislodged material.

2. The apparatus as claimed in claim 1, wherein the substrate holder has a pivot point, and the substrate holder is tiltable about the pivot point.

3. The apparatus as claimed in claim 1, further comprising a magnetic field generator configured for creating a magnetic field for accelerating the electrons.

4. A method for forming an antireflection film on an optical substrate, characterized in that the method comprises the steps of:
providing an apparatus of claim 1; and
tilting the optical substrate during deposition of the material of the at least one evaporation source on the optical substrate.

5. The method as claimed in claim 4, wherein the substrate holder has a pivoted point, the substrate holder is rotated about the pivoted point during deposition of the material of the at least one evaporation source on the optical substrate.

6. The method as claimed in claim 4, wherein the incident angle of the dislodged material is changed periodically.
